(19) United States
(12) Patent Application Publication
(10) Pub. No.: US 2008/0299764 A1
(43) Pub. Date: Dec. 4, 2008

(54) Interconnection having dual-level or multi-level capping layer and method of forming the same

(76) Inventors: Jun-Hwan Oh, Incheon Metropolitan City (KR); Dong-Cho Maeng, Yongin-si (KR)

Correspondence Address: HARNESS, DICKEY & PIERCE, P.L.C., P.O. BOX 8910, RESTON, VA, 20195, US

(21) Appl. No.: 12/222,347

(22) Filed: Aug. 7, 2008

Related U.S. Application Data
(62) Division of application No. 11/488,058, filed on Jul. 18, 2006.

(30) Foreign Application Priority Data
Jul. 20, 2005 (KR) 10-2005-0066007

(51) Int. Cl. H01L 21/4763

(52) U.S. Cl. 438/643; 257/E21.495

(57) ABSTRACT

An interconnection having a dual-level and multi-level capping layer and a method of forming the same. The interconnection may include an interlayer dielectric layer with a groove formed therein, a metal layer formed within the groove, a metal compound layer on the metal layer, a first barrier layer on the interlayer dielectric layer, and a second barrier layer on both the metal compound layer and the first barrier layer.

### PRIORITY STATEMENT

This application is based on and claims priority from Korean Patent Application No. 10-2005-0066007 filed on Jul. 20, 2005 in the Korean Intellectual Property Office, the disclosure of which is incorporated herein in its entirety by reference.

### BACKGROUND OF THE INVENTION

1. Field of the Invention

Example embodiments of the present invention relate to an interconnection for use in semiconductor devices and a method for forming the same. For example, example embodiments of the present invention relate to a single, dual, or multi damascene interconnection formed within an interlayer dielectric layer and coated with a barrier layer, and a method for forming the same.

2. Description of the Related Art

In order to increase the speed of semiconductor devices, thicknesses of gate oxide layers and lengths of gates may be reduced. However, the resistance of wires and the capacitance of interlayer dielectrics may cause an RC delay, which may decrease the device speed. Effort has been made to reduce the RC delay by employing wires having lower resistances and/or interlayer dielectrics having lower dielectric constants.

Aluminum (Al) was once a popular wiring material, but copper (Cu) has been recently used for wiring in place of aluminum because of its improved physical properties. For example, copper wires allow higher signal transmission speeds due to its lower specific resistance, which is half that of aluminum. Further, copper's higher resistance to electromigration may improve the reliability of the device.

However, it is difficult to etch copper into desired patterns. To overcome this, a damascene process may be utilized, in which grooves for interconnection patterns are first defined in a dielectric layer via lithography, metal layers are formed to fill the grooves, and excess metal layers are removed by CMP (chemical-mechanical polishing). For example, attention has been paid to a dual damascene process in which both a via hole and a trench region formed within a dielectric layer are filled with copper by means of a single round of deposition, which is followed by planarization.

In order to better understand the background of the invention, a description is given of a conventional damascene process in the following.

With reference to FIG. 1, an interconnection metal line is delineated by a conventional damascene metallization process. As seen in this cross-sectional view, a metal layer 103 may be surrounded by a barrier metal layer (not shown), filling a groove formed within an interlayer dielectric layer 101 on a substrate 100. A capping layer 105 may be formed over both the interlayer dielectric layer 101 and the metal layer 103. The capping layer 105, which may be deposited on the metal layer 103 after CMP of copper in a damascene process, may prevent the diffusion of copper and to impart a higher etch selectivity for an interlayer dielectric to be formed over the metal layer 103. The recent demand for a lower dielectric material (for example, having a dielectric constant of 2-4) as an interlayer dielectric layer has recently caused attention to be paid to silicon carbide, in addition to silicon nitride. Because silicon carbide has a higher etch selectivity with regard to lower dielectric films and a dielectric constant of 4 to 5, which is lower than that of silicon nitride, it may be used as a capping layer after CMP. When silicon carbide is used as a capping layer, however, inferior leakage damping properties may be obtained at the interface with the CMP surface than when silicon nitride is used. Additionally, stress may be concentrated in the region where a via-hole is formed, producing a stress gradient, and stress-induced vacancies or voids may be formed through the grain boundaries of the metal layer, resulting in electrical defects. As a rule, lower dielectric (low-K) materials may suffer from this problem because they have lower porosity and mechanical hardness but larger coefficients of thermal expansion.

### SUMMARY OF THE INVENTION

In accordance with an example embodiment of the present invention, an interconnection of a semiconductor device is provided that includes an interlayer dielectric layer with a groove formed therein, a metal layer formed within the groove, a metal compound positioned atop the metal layer, a first barrier layer positioned atop the interlayer dielectric layer, and a second barrier layer positioned atop both the metal compound layer and the first barrier layer.

In accordance with another embodiment of the present invention, a method for forming an interconnection of a semiconductor device is provided that includes forming an interlayer dielectric layer on a substrate, forming a groove in the interlayer dielectric layer, forming a metal layer to fill the groove, forming a first barrier layer over both the metal layer and the interlayer dielectric layer, thermally treating the resultant substrate including the first barrier layer to form a metal compound layer atop the metal layer, and forming a second barrier layer over the thermally treated substrate including the first barrier layer.

### BRIEF DESCRIPTION OF THE DRAWINGS

The above and other objects, features and advantages of example embodiments of the present invention will be more clearly understood from the following detailed description taken in conjunction with the accompanying drawings, in which:

FIG. 1 is a schematic cross-sectional view showing a conventional interconnection;

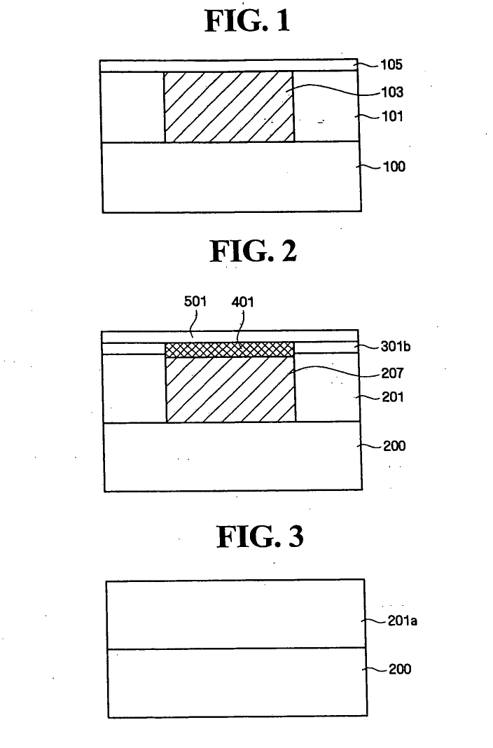

FIG. 2 is a schematic cross-sectional view showing an interconnection in accordance with an example embodiment of the present invention; and

FIGS. 3 to 9 are schematic cross-sectional views showing a method for forming an interconnection in accordance with an example embodiment of the present invention.

### DETAILED DESCRIPTION OF EXAMPLE EMBODIMENTS OF THE INVENTION

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Also, the use of the words “compound,” “compounds,” or “compound(s),” refer to either a single compound or to a plurality of compounds. These words are used to denote one or more compounds but may also just indicate a single compound.

Now, in order to more specifically describe example embodiments of the present invention, various embodiments of the present invention will be described in detail with reference to the attached drawings. However, the present invention is not limited to the example embodiments, but may be embodied in various forms. In the figures, if a layer is formed on another layer or a substrate, it means that the layer is directly formed on another layer or a substrate, or that a third layer is interposed therebetween. In the following description, the same reference numerals denote the same elements.

Although the example embodiments of the present invention have been disclosed for illustrative purposes, those skilled in the art will appreciate that various modifications, additions and substitutions are possible, without departing from the scope and spirit of the invention as disclosed in the accompanying claims.

Hereinafter, example embodiments of the present invention will be described in detail with reference to the accompanying drawings. The aspects and features of example embodiments of the present invention and methods for achieving the aspects and features will become apparent by referring to the embodiments to be described in detail with reference to the accompanying drawings. However, example embodiments of the present invention are not limited to example embodiments disclosed hereinafter, but may be implemented in diverse forms. The matter defined in the description, such as the detailed construction and elements, are provided to assist those of ordinary skill in the art in a comprehensive understanding of example embodiments of the invention, and example embodiments of the present invention are only defined within the scope of the appended claims. In the entire description of example embodiments of the present invention, the same drawing reference numerals are used for the same elements across various figures.

For the sake of convenience, the following description is made taking copper interconnects as an example, and it should be understood that all lower-resistance conductors, for example, aluminum (Al), gold (Au), and alloys thereof may also be used.

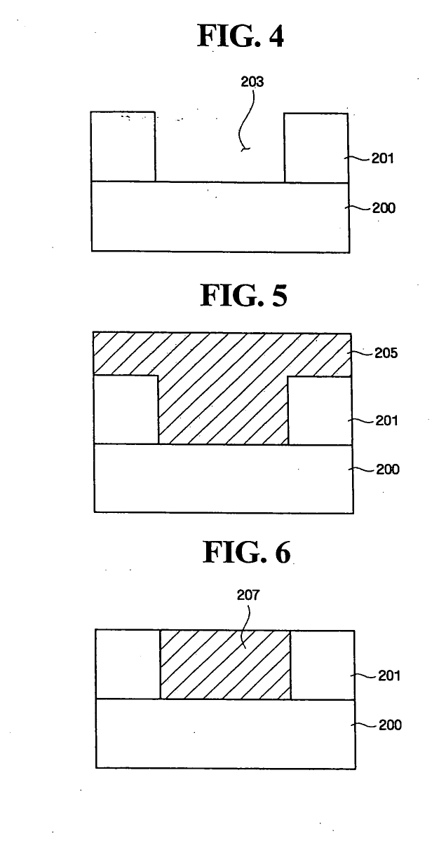

FIG. 2 is a schematic cross-sectional view showing an interconnection of a semiconductor device in accordance with an example embodiment of the present invention.

With reference to FIG. 2, an interlayer dielectric layer 201 having a groove therein is formed on a substrate 200, and a metal layer 207 is formed in the groove of the interlayer dielectric layer 201.

Optionally, there may be a conducting layer made from polysilicon, tungsten (W), aluminum (Al) or copper (Cu) or an insulating layer interposed between the substrate 200 and the interlayer dielectric layer 201.

The interlayer dielectric layer 201 may include a plurality of insulating layers. The plurality of insulating layers may be oxides with a wire pattern groove. For reduction of the RC delay, the insulating layer(s) may have lower dielectric constants. For example, the insulating layer(s) may be made of black diamond, FSG (fluorine silicate glass), SiOC, polyimide or SiLK™, but are not limited thereto.

The metal layer 207 may be made of copper or a copper alloy, but is not limited thereto. The term “copper alloy” as used herein means copper incorporated with a trace amount of another element, such as C, Ag, Co, Ta, A, Zn, Mn, Ti, Mg, Cr, Ge, Sr, Pt, Mg, Al and/or Zr, which are given as illustrative, non-limitative examples.

A barrier metal layer (not shown) may be further interposed between a surface of the interlayer dielectric layer 201 and the metal layer 207; and may reduce or prevent the diffusion of metal atoms from the groove filled with the metal layer 207 into the interlayer dielectric layer 201. is the barrier metal layer may be formed to a thickness from about 200 to about 1,000 Å, for example, to a thickness of about 450 Å. As a material for the barrier metal layer, titanium (Ti), tantalum (Ta), tungsten (W) or nitrides thereof, for example, TiN, TaN, and WN, may be used. In addition, TaSiN, WSiN or TiSiN may be used. The barrier metal layer may be deposited in a CVD (chemical vapor deposition) process or a PVD (physical vapor deposition) process, for example, sputtering.

A seed metal layer may be formed on the barrier metal layer, to increase the uniformity of the interconnection and/or to initiate nucleation. If formed, the seed metal layer may range in thickness from about 500 to about 2,500 Å, for example, about 1,500 Å thick. The seed metal may be copper, gold, silver, platinum (Pt), or palladium (Pd), but is not limited thereto.

On the metal layer 207 may be provided a metal compound layer 401 which may serve as a barrier layer to the metal layer 207. The metal compound layer 401 may contain the metal component of the metal layer 207 and silicon, and optionally nitrogen.

On the interlayer dielectric layer 201, a first barrier layer 301b may be formed to a thickness of about 100 Å or less. The first barrier layer 301b may be made of silicon nitride (SiN), silicon carbide (SiC) or silicon carbon nitride (SiCN), but is not limited thereto.

A second barrier layer 501 may be formed over both the metal compound layer 401 and the first barrier layer 301b. The second barrier layer 501 may range in thickness from about 100 to about 1,000 Å. The second barrier layer 501 may be made from silicon nitride (SiN), silicon carbide (SiC), or silicon carbon nitride (SiCN), but is not limited thereto. As described, a barrier layer is, in duplicate, formed over the metal layer 207 and the interlayer dielectric layer 201.

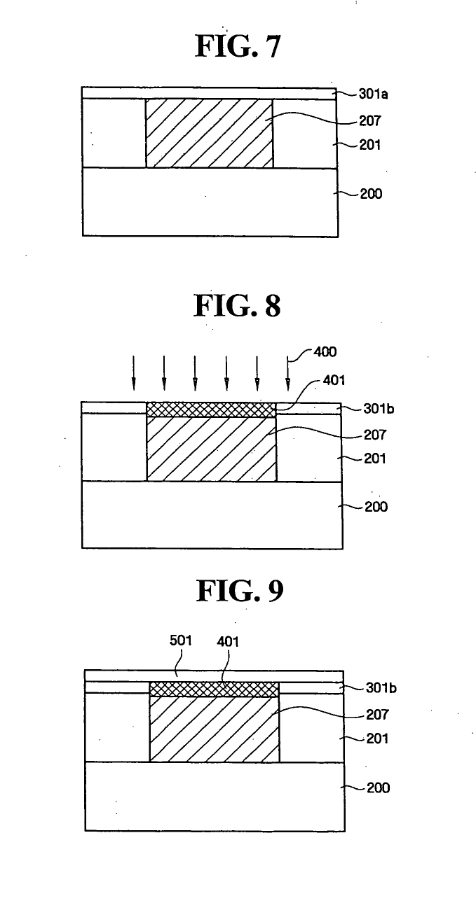

A method for forming an interconnection of a semiconductor device in an example embodiment of the present invention is shown in FIGS. 3 to 9.

As shown in FIG. 3, an interlayer dielectric layer 201a may be formed on a substrate 200. Optionally, a conductive material, for example, polysilicon, tungsten (W), aluminum, or copper, or an insulator may be interposed between the substrate 200 and the interlayer dielectric layer 201a The interlayer dielectric layer 201a may include a plurality of insulating layers. The plurality of insulating layers may be oxides with a wire pattern groove. In order to reduce the RC delay, the plurality of insulating layers may have lower dielectric constants. For example, the insulating layers may be made of black diamond, FSG (fluorine silicate glass), SiOC, polyimide or SiLK™, but are not limited thereto.

As shown in FIG. 4, the interlayer dielectric layer 201a may be partially etched to form a groove 203 in a desired wire pattern. This pattern, although depicted in the form of a single damascene interconnection, may be in the form of a dual or multiple damascene interconnection. The resulting structure having the groove 203 may be rinsed, and a barrier metal layer (not shown) may be applied thereon. If present, the barrier metal layer may reduce or prevent the diffusion of metal atoms of the metal layer filling the groove 203 into the interlayer dielectric layer 201. is the barrier layer may be formed to a thickness in the range of about 200 to about 1,000 Å, for example, to a thickness of about 450 Å. As a material for the barrier metal layer, titanium (Ti), tantalum (Ta), tungsten (W) or nitrides thereof, for example, TiN, TaN, and WN, may be used. In addition, TaSiN, WSiN and TiSiN may be used. The barrier layer may be deposited in a CVD (chemical vapor deposition) process or a PVD (physical vapor deposition) process, for example sputtering.

As shown in FIG. 5 a metal layer 205 may be formed to cover the interlayer dielectric layer 201 as well as to fill the groove 203. The metal layer 205 may be made from copper or a copper alloy, but is not limited thereto. The term “copper alloy” as used herein means copper incorporated with a trace amount of another element, such as C, Ag, Co, Ta, In, Zn, Mn, Ti, Mg, Cr, Ge, Sr, Pt, Mg, Al or Zr.

In order to fill the groove 203 with a metal layer such as copper, a sputtering process or a CVD process may be used. Also, a plating process (either electroplating or electroless plating) may be used. Upon plating, the introduction of a seed metal layer onto the barrier metal layer may improve results. The seed metal layer may increase the uniformity of the plated layer and assist in nucleation in an early phase. If formed, the seed metal layer may range in thickness from about 500 to about 2,500 Å, for example, about 1,500 Å thick. For the deposition of the seed metal layer, a CVD process may be used, but a sputtering process may also be used. In this regard, sputtering may be performed at a sputter power of about 2 kW and a substrate temperature of about 0° C. under a pressure of about 2 mTorr with the substrate 60 mm from the target, but is not limited to these conditions. Depending upon the deposition method used, the seed metal may be selected from copper, gold, silver, platinum (Pt), palladium (Pd), and the like. After being plated, the copper layer may have a sparse texture structure in which very small grains are arranged with large intervals therebetween. Thus, an annealing process may be conducted so that the grains grow through recrystallization, thereby reducing the specific resistance.

Alternatively, a sputtering or CVD process may be used to fill the groove with copper. Also, a metal having a resistance suitable for use in a wire, for example, gold, platinum or silver, may be deposited instead of copper. In consideration of the allowance for the subsequent CMP, the metal layer may be deposited to a thickness about 0.2 μm greater than the depth of the groove.

Referring to FIG. 6, the resulting structure may be planarized using a CMP process until the upper surface of the interlayer dielectric layer 201 is exposed to form a metal layer 207 in a damascene interconnection pattern, the upper surface of which may be substantially incident with that of the metal layer 207. It may be difficult to maintain an oxygen-free state during the formation of the metal layer 207, and may be difficult when a reaction furnace is used. Further, a slurry of the CMP process may contain oxygen. Thus, the copper layer, when formed, may have spontaneously generated copper oxide, such as CuO or Cu₂O, on its surface. The copper oxide may undermine the adhesiveness between the copper layer and the layer deposited thereon and increase the resistance, thereby degrading the reliability of the final product.

To eliminate the copper oxide, the plasma may be prepared by applying a RF to a gas mixture of Ar, He, H₂, etc.; for example, hydrogen-based plasma may be utilized. Alternatively, an NH₃-based plasma prepared by applying a RF to a gas mixture of Ar, He, NH₃, etc. may be used. In this example, the surface of the metal layer 207 may not only be reduced but also nitrified.

Thereafter, as shown in FIG. 7, a first barrier layer 301a may be formed over the entire upper surface of the resulting structure. Silicon nitride may be used for this deposition. Silicon nitride may be deposited using a CVD process, or to a thickness of about 100 Å using a PECVD (plasma enhanced CVD) process. The formation of the silicon nitride layer may be performed in-situ with the plasma treatment, which may be simpler than performing two separate processes. The in-situ process may reduce or prevent the formation of a copper oxide layer on the interconnection. In place of silicon nitride, silicon carbide (SiC) or silicon carbon nitride (SiCN) may also be used for the formation of the first barrier layer.

As shown in FIG. 8, the resulting structure, in which the first barrier layer is formed, may be subjected to thermal annealing 400. For example, a rapid thermal annealing (RTA) process may be performed. Alternatively, a vacuum annealing or a plasma annealing process may be utilized. The thermal annealing process 400 may be performed at about 200 to about 650° C. The metal layer 207 may be reacted with a component of the first barrier layer, for example, silicon nitride, at an upper surface thereof to form a metal compound layer 401, for example, a silicide layer. For example, the elements of CuSiN may react with copper at their respective stoichiometric ratios to form the metal compound layer 401. The first barrier layer 301b located on the interlayer dielectric layer 201 may remain unreacted and thus may serve as a barrier to the interlayer dielectric layer.

As shown in FIG. 9, a second barrier layer 501 may be formed with silicon nitride (SiN), silicon carbide (SiC) or silicon carbon nitride (SiCN). The same process as was used for the first barrier layer may be applied for the formation of the second barrier layer. In an example embodiment, silicon nitride may be used for the first barrier layer while silicon carbide may be used for the second barrier layer. The double-level capping layer including silicon nitride and silicon carbide may show a synergistic effect therebetween. That is, because the silicon nitride layer complements leaky parts while the silicon carbide layer is responsible for a large etch selectivity, the double-level capping layer may satisfy both leakage reduction and large etch selectivity properties.

When a contact region is constructed over the metal layer, the interposition of the metal compound layer and the second barrier layer between the contact region and the metal layer may reduce or prevent defects caused by stress-induced vacancies and/or voids.

As previously described, the damascene interconnection in accordance with example embodiments of the present invention may be structured to have a dual barrier layer including a metal compound layer as a capping layer, thereby improving the reduction or prevention of both leakage and defects caused by stress-induced vacancies and/or voids.

According to some example embodiments of the present invention, a barrier layer may have N barrier layers, where N>2 with one or more of the barrier layers being made of substantially different materials.

Although example embodiments of the present invention have been disclosed for illustrative purposes, those skilled in the art will appreciate that various modifications, additions and substitutions are possible, without departing from the scope and spirit of the invention as disclosed in the accompanying claims.

1.-7. (canceled)

8. A method of forming an interconnection of a semiconductor device, comprising:
forming an interlayer dielectric layer on a substrate;
forming a groove in the interlayer dielectric layer;
filling the groove with a metal layer;
forming a first barrier layer over both the metal layer and the interlayer dielectric layer;
thermally treating the resultant substrate including the first barrier layer to form a metal compound layer atop the metal layer; and
forming a second barrier layer over the thermally treated substrate including the first barrier layer.

9. The method of claim 8, wherein filling the groove is performed using a damascene process.

10. The method of claim 8, further comprising forming a barrier metal layer between forming the groove in the interlayer dielectric layer and filling the groove.

11. The method of claim 8, wherein the first barrier layer is made of at least one material selected from silicon nitride (SiN), silicon carbide (SiC) and silicon carbon nitride (SiCN).

12. The method of claim 8, wherein the thermal treating is performed in a temperature range of about 200 to about 650° C.

13. The method of claim 8, wherein the thermal treating is performed utilizing a rapid thermal annealing (RTA) process.

14. The method of claim 8, wherein the thermal treating is performed using a vacuum annealing process.

15. The method of claim 8, wherein the thermal treating is performed using a plasma annealing process.

16. The method of claim 8, wherein the second barrier layer is made of at least one material selected from silicon nitride (SiN), silicon carbide (SiC) and silicon carbon nitride (SiCN).

17. The method of claim 16, wherein the second barrier layer has a thickness in a range of about 100 to about 1,000 Å.
